(19) United States
(12) Patent Application Publication
(10) Pub. No.: US 2021/0136950 A1
(43) Pub. Date: May 6, 2021

(54) AIRFLOW CHANNELS BETWEEN HOUSINGS

(71) Applicant: HEWLETT-PACKARD DEVELOPMENT COMPANY, L.P., Houston, TX (US)

(72) Inventors: Timothy J. SUTHERLAND, San Diego, CA (US); Philip H. WRIGHT, San Diego, CA (US); Owen P. COLUMBUS, San Diego, CA (US)

(73) Assignee: HEWLETT-PACKARD DEVELOPMENT COMPANY, L.P., Houston, TX (US)

(21) Appl. No.: 16/074,171

(22) PCT Filed: Oct. 4, 2016
(86) PCT No.: PCT/US2016/055343

§ 371 Date: Jul. 31, 2018

(51) Int. Cl. H05K 7/20; G06F 1/20

(52) U.S. Cl. CPC H05K 7/20145; H05K 7/20154; G06F 1/203

(57) ABSTRACT

In some examples, an electronic device includes a first housing providing a sealed inner chamber, an electronic component inside the sealed inner chamber, a second housing externally of the first housing, the second housing comprising a first opening and a second opening, and an airflow channel between the first housing and second housing, the airflow channel to direct airflow from the first opening to the second opening through the airflow channel to carry heat away from a surface of the first housing.

### BACKGROUND

During operation of an electronic device, active electronic components in the electronic device can produce heat. An electronic device can include a cooling mechanism to cool the heat producing components. A cooling mechanism can include a passive cooling mechanism such as a heat sink that can be attached to a heat producing component. In other examples, a cooling mechanism can include an airflow generator, such as a fan, to generate cooling airflow to assist in cooling the active electronic components.

### BRIEF DESCRIPTION OF THE DRAWINGS

Some implementations of the present disclosure are described with respect to the following figures.

FIG. 1 is a rear view of an electronic device according to some examples.

FIG. 2 is a cross-sectional side view of the electronic device of FIG. 1, according to some examples.

FIG. 3 is a rear view of an electronic device according to further examples.

FIG. 4 is a rear view of the electronic device of FIG. 3 in a different orientation, according to further examples.

FIG. 5 is a flow diagram of a process of forming an electronic device according to some examples.

FIG. 6 illustrates a system including an electronic device docked to a docking station, according to alternative examples.

### DETAILED DESCRIPTION

In the present disclosure, the article “a,” “an”, or “the” can be used to refer to a singular element, or alternatively to multiple elements unless the context clearly indicates otherwise. Also, the term “includes,” “including,” “comprises,” “comprising,” “have,” or “having” is open ended and specifies the presence of the stated element(s), but does not preclude the presence or addition of other elements.

The presence of a cooling mechanism in an electronic device can take up valuable space in the electronic device, especially for electronic devices with small form factors (e.g., electronic devices with thin profiles or that have small footprints). Examples of small electronic devices include handheld devices or wearable devices. Handheld devices can include a tablet computer, a smart phone, a game appliance, or any other electronic device that can be held by a hand (or hands) of a user during operation of the electronic device. Wearable devices can include a smart watch, a head-worn device such as a smart watch, smart eyeglasses, a head-mounted device, or any other electronic device that can be worn on a body of a user.

The cooling of small electronic devices can be challenging, particularly small electronic devices that have high performance processors or other electronic components that can heat up quickly during active use.

Since a small electronic device such as a handheld device or a wearable device is intended to be in continual contact with a part of a user during use, it is desired that a surface temperature of the small electronic device (where the surface temperature is the temperature of a surface of the electronic device that touches a user during use) be less than a target temperature, such as 48° Celsius (or some other temperature value). If the surface temperature of the electronic device exceeds the target threshold, then a user may experience discomfort due to touching of a hot surface.

However, a small electronic device has a thin profile and/or a small footprint, which can make it challenging to include an effective cooling mechanism within the small electronic device to prevent the surface temperature of the small electronic device from rising above the target temperature. In accordance with some implementations of the present disclosure, cooling mechanisms or techniques are provided to reduce a surface temperature of surfaces of electronic devices. In some examples, electronic devices have housings that provide sealed inner chambers for housing electronic components. A sealed inner chamber of an electronic device protects an electronic component inside the sealed inner chamber from damage in case the electronic device is exposed to liquid, such as by being splashed with liquid, or when dropped into liquid. In accordance with some implementations, an airflow channel for cooling a heat-producing electronic component of an electronic device can be defined between a main housing that defines a sealed inner chamber and an outer housing that is in contact with a user during use.

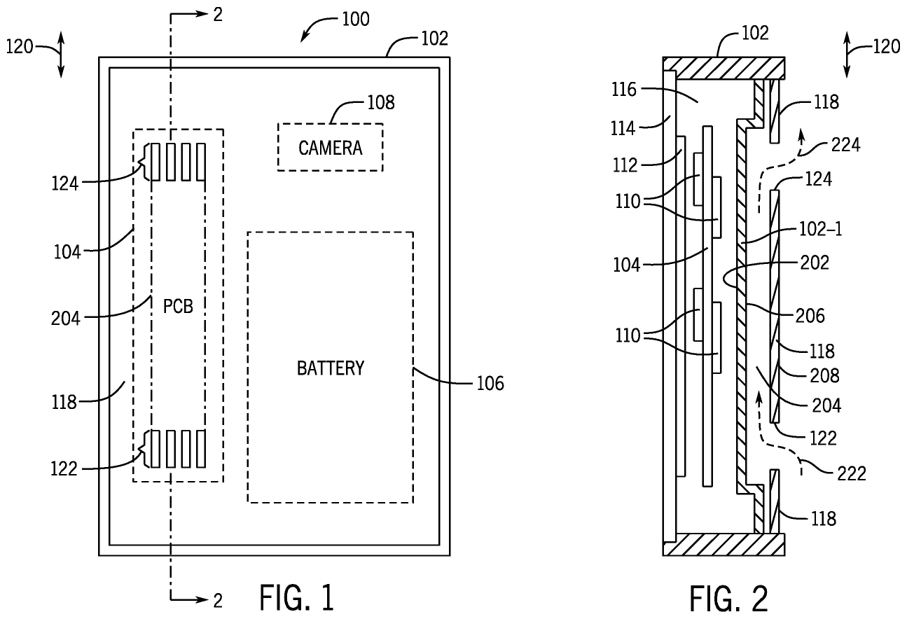

FIG. 1 is a rear view of an electronic device 100, such as a handheld device. For example, the electronic device 100 shown in FIG. 1 can be a smart phone or a tablet computer or another type of handheld device. FIG. 2 is a cross-sectional view of the electronic device 100 along section 2-2. Although a specific type of electronic device is depicted in FIGS. 1 and 2, it is noted that techniques or mechanisms according to some implementations can be applied to other types of electronic devices, such as wearable devices or other electronic devices.

The electronic device 100 has a main housing 102 to house various components of the electronic device 100. Note that the term “housing” can refer to a single housing structure, or multiple housing structures that are attached together. The components inside the electronic device 100 are shown in dashed profile in FIG. 1 to indicate that such components are contained inside an inner chamber of the electronic device 100.

In some examples, the components inside the electronic device 100 include a printed circuit board (PCB) 104, on which electronic components 110 can be mounted. As shown in FIG. 2, the PCB 104 has multiple electronic components 110 mounted to both surfaces of the PCB 104. Examples of the electronic components 110 include any or some combination of the following: a processor, a memory device, an input/output device, and so forth. The electronic components 110 can be active electronic components that can produce heat during operation of the electronic components.

In addition, the components inside the electronic device 100 can include a battery 106 to provide power to electronic components in the electronic device 100. A camera 108 can also be included in the electronic device 100. Although specific components are identified in FIG. 1, it is noted that in other examples, alternative or additional components can be provided.

More generally, the electronic device 100 includes an electronic component that during operation can produce heat inside the electronic device 100. Such heat if not properly dissipated can cause an outer surface of the electronic device 100 to increase in temperature. If the surface temperature of the electronic device 100 exceeds a target temperature, then the surface can become too hot, and thus can cause discomfort to a user that is in contact with the hot surface.

Heat produced by some electronic components 110 during operation can cause a rear housing portion 102-1 of the main housing 102 to heat up. The rear housing portion 102-1 can be formed of a thermally conductive material, such as metal or another material. In some examples, an inner surface 202 of the rear housing portion 102-1 can thermally contact, either directly or indirectly through a thermal paste or other thermal layer, an electronic component 110 (or multiple electronic components 110). In other examples, the inner surface 202 of the rear housing portion 102-1 does not thermally contact any of the electronic components 110, but thermal radiation from the electronic components 110 can cause heating of the rear housing portion 102-1.

As further shown in FIG. 2, the electronic device 100 further includes a display assembly that has a display panel 112 and a display cover 114. The display cover 114 lies over a surface of the display panel 112 to protect the display panel 112. The display cover 114 can be formed of a glass, a transparent plastic, or any other material that is transparent. The display panel 112 can include a liquid crystal display (LCD) panel, an organic light-emitting diode (OLED) display panel, or any other type of display panel that can display an image when activated. The image displayed by the display panel 112 is visible through the display cover 114 to a user of the electronic device 100.

The display cover 114 can be considered to be part of the main housing 102, since the combination of the main housing 102 (including the rear housing portion 102-1) and the display cover 114 defines an inner chamber 116 inside the electronic device 100. In some implementations, the inner chamber 116 is a hermetically sealed inner chamber. By being hermetically sealed, the inner chamber 116 can contain a gas or a liquid that does not leak out through the main housing (which can include members 102, 102-1, and 114). Hermetically sealing the components inside the inner chamber 116 can protect such components from damage due to exposure of the electronic device 100 to a liquid, such as water or other liquid. For example, the electronic device 100 may be splashed with liquid, or the electronic device 100 can be dropped into liquid. The liquid does not penetrate into the inner chamber 116, and thus the electronic components inside the inner chamber 116 are protected from damage due to liquid exposure.

The electronic device 100 further includes an outer housing 118, which is provided externally of the main housing 102. In examples according to FIGS. 1 and 2, the outer housing 118 is provided at the rear of the electronic device 100 (while the display cover is provided at the front of the electronic device 100). More specifically, the outer housing 118 is arranged externally of the rear housing portion 102-1 of the main housing 102. The outer housing 118 is the part of the electronic device 100 that a user is likely to contact during use of the electronic device 100, since the electronic device 100 is held or worn by the user during use.

By arranging the outer housing 118 external of the rear housing portion 102-1, an airflow channel 204 is formed between the outer housing 118 and the rear housing portion 102-1. The airflow channel 204 extends generally along a length of the electronic device 100, as indicated by axis 120 shown in each of FIGS. 1 and 2.

FIGS. 1 and 2 also show that the outer housing 118 is formed with lower openings 122 and upper openings 124. The openings 122 and 124 are formed through a wall of the outer housing 118. Although multiple lower openings 122 and multiple upper openings 124 are shown in FIG. 1, it is noted that in other examples, a single lower opening 122 and a single upper opening 124 can be formed in the outer housing 118.

Incoming airflow 222 can flow into the airflow channel 204 through the lower openings 122, and the air can flow upwardly along the airflow channel 204. Air in the airflow channel 204 is heated by a hot outer surface 206 of the rear housing portion 102-1, as heated by heat produced from the electronic components 110.

The heated airflow rises in the airflow channel 204 and exits through the upper openings 124 as heated outgoing airflow 224. The combination of the openings 122, 124, and the airflow channel 204 provides a chimney effect for cooling the heated rear housing portion 102-1 during the operation of the electronic device 100. Since hot air rises, natural convection occurs to provide a continual flow of air through the airflow channel 204 for cooling the rear housing portion 102-1. The cooling of the rear housing portion 102-1 allows for heat transferred to the rear housing portion 102-1 from the electronic components 110 to be directed away from the electronic device 100 through the upper openings 124.

Moreover, since the heated airflow is directed through the airflow channel 204 and exits through the upper openings 224, the temperature of an outer surface 208 of the outer housing 118 can be kept below a target temperature, such as 48° Celsius or another target temperature, to prevent a user from discomfort.

In further examples, if the electronic device 100 were to be held in an upside down orientation from the orientation shown in FIGS. 1 and 2, then airflow would flow into the openings 124 and exit through the openings 122.

The orientation of the electronic device 100 shown in FIGS. 1 and 2 (or the opposite orientation where the electronic device 100 is upside down) is referred to as a portrait orientation of the electronic device 100, where the dimension of the electronic device 100 in the vertical direction is longer than the dimension of the electronic device 100 in the horizontal direction. In other examples, the electronic device 100 can have a landscape orientation, where the electronic device 100 is rotated by 90° with respect to the orientation shown in FIGS. 1 and 2. In the landscape orientation, the dimension of the electronic device 100 in the horizontal direction is longer than the dimension of the electronic device 100 in the vertical direction.

In the portrait orientation, the airflow channel 114 extends substantially in the vertical direction. “Substantially” in the vertical direction can refer to a vertical direction, or a direction where there is a vertical component. For example, a diagonal direction of the airflow channel 204 has a vertical component, and so such an airflow channel is considered to substantially extend in a vertical direction. In further examples, an airflow channel extending substantially in a vertical orientation can refer to the airflow channel extending along the vertical direction, or within 45° of the vertical direction.

As further shown in FIG. 1, the positioning of the openings 122 and 124 and the airflow channel 204 is such that the majority of the airflow occurs over a portion of the main housing portion 102-1 that is adjacent the PCB 104 on which the electronic components 110 are mounted. In other examples, the openings 122, 124, and the airflow channel 204 can be positioned to allow airflow over the battery, the camera 108, and/or any other component within the electronic device 100 that can produce heat during operation.

Although reference is made to just one airflow channel 204, it is noted that in other examples, multiple airflow channels can be provided between the rear housing portion 102-1 of the main housing 102 and the outer housing 118, for cooling respective portions of the electronic device 100.

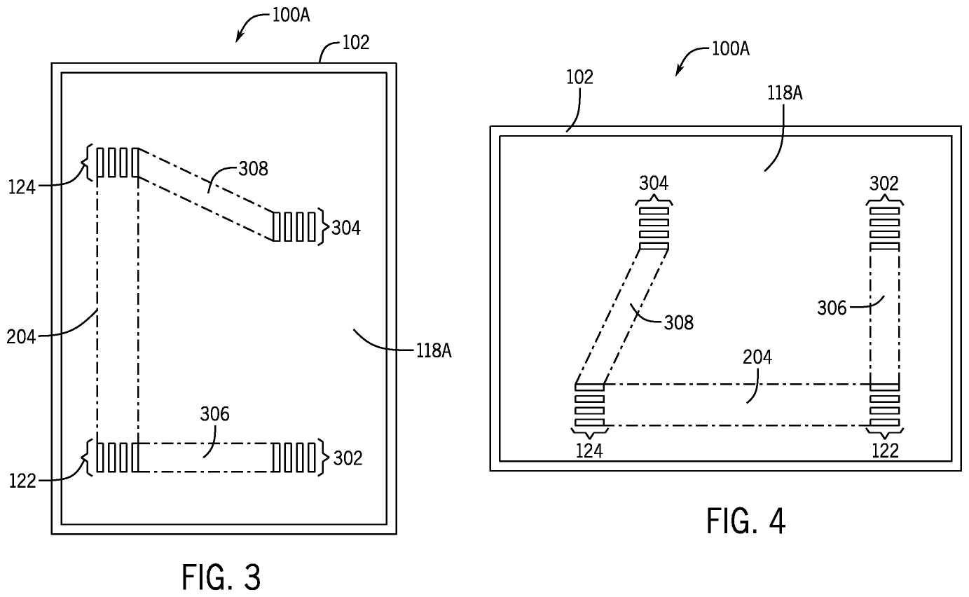

FIG. 3 is a rear view of an electronic device 100A according to further examples. The electronic device 100A has elements that are similar to elements shown in FIGS. 1 and 2, except that additional sets of openings 302 and 304 are provided in an outer housing 118A of the electronic device 100A. The sets of openings 302 and 304 are arranged laterally to a side of respective sets of openings 122 and 124.

As shown in dashed profile, in addition to the airflow channel 204 between openings 122 and openings 124, another airflow channel 306 can extend between the openings 122 and the openings 302, and a further airflow channel 308 can extend between the openings 124 and 304. In the portrait orientation of the electronic device 100A shown in FIG. 3, the airflow channel 204 extends substantially in the vertical direction, the airflow channel 306 extends substantially in the horizontal orientation, while the airflow channel 308 extends in a diagonal orientation. “Substantially” in the horizontal direction can refer to a horizontal direction, or a direction where there is a horizontal component. For example, a diagonal direction of an airflow channel can have a horizontal component, and so such an airflow channel is considered to substantially extend in a horizontal direction. In further examples, an airflow channel extending substantially in a horizontal orientation can refer to the airflow channel extending along the horizontal direction, or within 45° of the horizontal direction.

A landscape orientation of the electronic device 100A is shown in FIG. 4, where the electronic device 100A is rotated 90° with respect to the portrait orientation shown in FIG. 3. In the landscape orientation shown in FIG. 4, the airflow channel 306 extends substantially in the vertical orientation, and the diagonal airflow channel 308 also has a vertical component. Thus, heated airflow can flow upwardly in each of the airflow channels 306 and 308 to exit through respective openings 302 and 304.

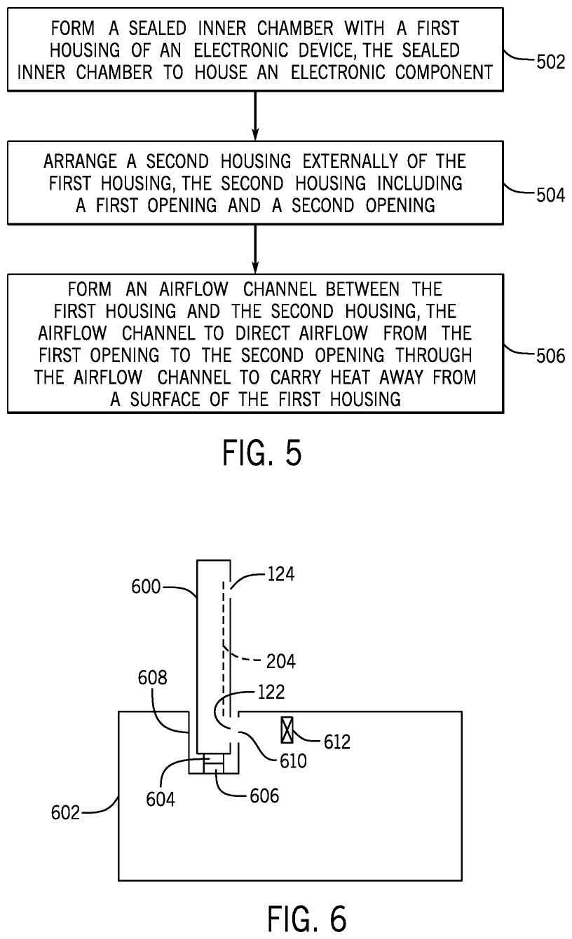

FIG. 5 is a flow diagram of an example process of forming an electronic device (e.g., 100 or 100A), according to some implementations. The process of FIG. 5 includes forming (at 502) a sealed inner chamber with a first housing (e.g., including 102, 102-1, and 114 in FIG. 2) of an electronic device, the sealed inner chamber to house an electronic component (e.g., 110 in FIG. 2). The process further includes arranging (at 504) a second housing (e.g., the outer housing 118 in FIGS. 1 and 2 or the outer housing 118A in FIGS. 3 and 4) externally of the first housing, the second housing comprising a first opening (e.g., 122, 124, 302, or 304) and a second opening (e.g., 124, 302, 304, or 122).

The process further includes forming (at 506) an airflow channel (e.g., 204, 306, or 308) between the first housing and the second housing, the airflow channel to direct airflow from the first opening to the second opening through the airflow channel to carry heat away from a surface of the first housing.

FIG. 6 shows an example system that includes an electronic device 600 (e.g., the electronic device 100 or 100A discussed above) docked to a docking station 602. A lower portion of the electronic device 600 has a docking connector 604, which can be removably connected to a mating connector 606 of the docking station 602 when the electronic device 600 is docked into a receptacle 608 of the docking station 602.

When the electronic device 600 is docked in the receptacle 608 of the docking station 602, the lower openings 122 of the electronic device 600 are aligned with an airflow outlet 610 of the docking station 602, where the airflow outlet 610 is positioned to direct airflow toward the receptacle 608. The docking station 602 has an airflow generator 612, which can include a fan (or alternatively, multiple fans). When activated, the airflow generator 612 produces a forced airflow that is directed out of the airflow outlet 610 and into the opening 122 of the electronic device 600. This forced airflow is directed into the airflow channel 204 inside the electronic device 600. The forced airflow flows at a higher rate than the natural convection through the airflow channel 204 due to rising hot air discussed above.

When the electronic device 600 is docked to the docking station 602, the electronic device 600 may be caused to operate at a higher level (e.g., the clock frequency of an electronic component such as a processor in the electronic device 600 can be run at a higher frequency, or the power supply voltage to an electronic component can be set at a higher voltage), which can cause increased heating by electronic components in the electronic device 600. The forced airflow can thus be more effective in removing the increased heat produced by the electronic components of the electronic device 600. When docked, the combination of the electronic device 600 and the docking station 602 can provide a more powerful computer. For example, the docking station 602 can include a larger display panel than the display panel of the electronic device 600. Also, the docking station 602 can include I/O components, such as a user input device, a network interface card, and so forth.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. An electronic device comprising:
a first housing providing a sealed inner chamber;
an electronic component inside the sealed inner chamber;
a second housing external of the first housing, the second housing comprising a first opening and a second opening; and
an airflow channel between the first housing and the second housing, the airflow channel to direct airflow from the first opening to the second opening through the airflow channel to carry heat away from a surface of the first housing.

2. The electronic device of claim 1, wherein the electronic device is a device to be carried or worn by a user, and the second housing comprises a surface exposed for contact to a human when the electronic device is held or worn by the user, wherein the first opening and the second opening are formed through a wall of the second housing.

3. The electronic device of claim 1, wherein the airflow channel extends substantially in a vertical orientation to allow heated air to rise in the airflow channel between the first and second openings.

4. The electronic device of claim 3, wherein the airflow channel extends substantially in the vertical orientation when the electronic device is in a portrait orientation.

5. The electronic device of claim 4, further comprising a third opening arranged laterally to one side of the first opening or the second opening, and a second airflow channel between the first opening or the second opening and the third opening, wherein the second airflow channel extends substantially in the vertical orientation when the electronic device is in a landscape orientation.

6. The electronic device of claim 1, wherein heat from the electronic component is thermally coupled to the first housing to cause the first housing to heat up, and wherein the airflow is to cool the surface of the first housing.

7. The electronic device of claim 6, wherein the first housing is formed of a thermally conductive material.

8. The electronic device of claim 1, further comprising a circuit board in the sealed inner chamber, and a plurality of electronic components mounted on the circuit board, the plurality of electronic components to produce heat during operation to heat the first housing.

9. A system comprising:
an electronic device comprising:
a main housing providing a sealed inner chamber;
an electronic component inside the sealed inner chamber;
an outer housing external of the main housing, the outer housing comprising a first opening and a second opening; and
an airflow channel extending along a length of the electronic device between the main housing and the outer housing, the airflow channel to direct airflow from the first opening to the second opening through the airflow channel to carry heat away from a surface of the main housing; and
a docking station to which the electronic device is dockable, the docking station comprising an airflow generator to generate a forced airflow directed into the first opening of the electronic device when docked in the docking station.

10. The system of claim 9, wherein the forced airflow provided by the airflow generator provides for increased heat dissipation of the electronic device when the electronic device is operated at a higher level while docked at the docking station.

11. The system of claim 9, wherein the electronic device further comprises a third opening arranged laterally to one side of the first opening or the second opening, and a second airflow channel between the first opening or the second opening and the third opening.

12. The system of claim 9, wherein, when the electronic device is docked to the docking station, the airflow channel extends substantially in a vertical orientation to allow heated air to rise in the airflow channel and exit through the second opening.

13. A method comprising:
forming a sealed inner chamber with a first housing of an electronic device, the sealed inner chamber to house an electronic component;
arranging a second housing externally of the first housing, the second housing comprising a first opening and a second opening; and
forming an airflow channel between the first housing and the second housing, the airflow channel to direct airflow from the first opening to the second opening through the airflow channel to carry heat away from a surface of the first housing.

14. The method of claim 13, further comprising:
arranging the first opening in the second housing to align with an airflow outlet of a docking station, wherein a forced airflow is produced by an airflow generator in the docking station for output through the airflow outlet into the first opening when the electronic device is docked to the docking station.

15. The method of claim 13, further comprising:
forming a third opening and a further airflow channel between the first or second opening and the third opening, to direct airflow through the further airflow channel from the first or second opening to the third opening.
